(19) United States
(12) Patent Application Publication
(10) Pub. No.: US 2026/0197964 A1
(43) Pub. Date: Jul. 9, 2026

(54) WIRELESS CHARGING DEVICE

(71) Applicant: Anker Innovations Technology Co., Ltd., CHANGSHA (CN)

(72) Inventors: Wei XIE, SHENZHEN (CN); Jing QIAN, SHENZHEN (CN); Boming HUANG, SHENZHEN (CN)

(21) Appl. No.: 19/556,934

(22) Filed: Mar. 4, 2026

Related U.S. Application Data
(63) Continuation of application No. PCT/CN2024/112638, filed on Aug. 16, 2024.

(30) Foreign Application Priority Data
Sep. 5, 2023 (CN) 202322406557.2

(51) Int. Cl. H05K 7/20; H02J 50/10; H02J 50/40; H02J 50/90; H02J 50/70

(52) U.S. Cl. CPC H05K 7/20145; H02J 50/10; H02J 50/402; H02J 50/90; H05K 7/20172; H02J 50/70

(57) ABSTRACT

The present application provides a wireless charging device, including a main body, a first wireless charging assembly, a first fan, and a second fan. The main body defines an accommodating cavity. The main body includes a first side plate configured to carry a device to be charged. An outer surface of the first side plate defines a first exhaust port. The first wireless charging assembly is disposed in the accommodating cavity. The first fan is disposed on the main body. The first fan defines a first air outlet. The first fan is configured to blow air toward the first exhaust port through the first air outlet. The second fan is disposed on the main body. The second fan defines a second air outlet. The second fan is configured to blow air toward the first wireless charging assembly through the second air outlet.

### CROSS-REFERENCE TO RELATED APPLICATIONS

This application is a continuation of International Patent Application No. PCT/CN2024/112638, filed on August 16, 2024, which claims priority to Chinese Patent Application No. 202322406557.2, filed on September 05, 2023, the contents of both are herein incorporated by reference in their entireties.

### TECHNICAL FIELD

The present disclosure relates to the field of wireless charging technologies, and in particular to a wireless charging device.

### BACKGROUND

With the development of wireless charging technology, an increasing number of electronic devices may support a wireless charging function. When the electronic device needs to be charged, the electronic device may be placed on a charging surface of a wireless charging device. That is, a wireless charging module of the wireless charging device may be configured to provide wireless charging for the electronic device. Compared with wired charging, wireless charging may eliminate a need for repeated plugging and unplugging during charging, thereby enabling charging upon placement and greatly improving charging convenience.

However, during a charging process, due to relatively low heat dissipation efficiency, heat generated by the electronic device and the wireless charging module may not be dissipated in a timely manner, resulting in relatively high temperatures of the electronic device and the wireless charging module, which may cause charging efficiency of the electronic device to decrease.

### SUMMARY

In a first aspect, some embodiments of the present disclosure may provide a wireless charging device. The wireless charging device may include a main body, a first wireless charging assembly, a first fan, and a second fan. The main body may define an accommodating cavity. The main body may include a first side plate. The first side plate may be configured to carry a device to be charged. An outer surface of the first side plate may define a first exhaust port. The first wireless charging assembly may be disposed in the accommodating cavity. The first fan may be disposed on the main body. The first fan may define a first air outlet. The first fan may be configured to blow air toward the first exhaust port through the first air outlet. The second fan may be disposed on the main body. The second fan may define a second air outlet. The second fan may be configured to blow air toward the first wireless charging assembly through the second air outlet.

In a second aspect, some embodiments of the present disclosure may further provide a wireless charging device. The wireless charging device may include a main body, a first wireless charging assembly, a first fan, and a second fan. The main body may define an accommodating cavity. The main body may include a first side plate. The first side plate may be configured to carry a device to be charged. An outer surface of the first side plate may define a first exhaust port. The first wireless charging assembly may be disposed in the accommodating cavity. The first fan may be disposed on the main body. The first fan may define a first air outlet. The first fan may be configured to blow air toward the first exhaust port through the first air outlet. The first air outlet may face toward the first exhaust port. A side of the first fan that defines the first air outlet may be in contact with the main body. The second fan may be disposed on the main body. The second fan may define a second air outlet. The second fan may be configured to blow air toward the first wireless charging assembly through the second air outlet.

### BRIEF DESCRIPTION OF THE DRAWINGS

In order to illustrate technical solutions in some embodiments of the present disclosure or in the related art more clearly, accompanying drawings required to be used in the descriptions of the embodiments or the related art may be briefly introduced below. Apparently, the accompanying drawings described below may be only some embodiments of the present disclosure. For those skilled in the art, other accompanying drawings may also be obtained based on these accompanying drawings without creative efforts.

FIG. 1 is a schematic structural view of a wireless charging device from a first perspective according to some embodiments of the present disclosure.

FIG. 2 is a schematic structural view of the wireless charging device from a second perspective according to some embodiments of the present disclosure.

FIG. 3 is an exploded schematic view of components of the wireless charging device according to some embodiments of the present disclosure.

FIG. 4 is a schematic cross-sectional structural view of the wireless charging device from a third perspective according to some embodiments of the present disclosure.

FIG. 5 is a schematic cross-sectional structural view of the wireless charging device from a fourth perspective according to some embodiments of the present disclosure.

### DETAILED DESCRIPTION

In order to make the objectives, technical solutions, and technical effects of the present disclosure more clearly understood, the present disclosure may be further described in detail below with reference to the accompanying drawings and embodiments. It should be understood that the embodiments described herein may be used only to explain the present disclosure and may not be used to limit the present disclosure.

Some embodiments of the present disclosure may provide a wireless charging device, so as to solve a problem in the related art that, due to relatively poor heat dissipation efficiency, heat generated from an electronic device and a wireless charging module may not be dissipated in a timely manner, resulting in relatively high temperatures of the electronic device and the wireless charging module, such that an internal temperature of a device to be charged may easily reach a preset temperature protection point, thereby causing a reduction in charging efficiency of the device to be charged.

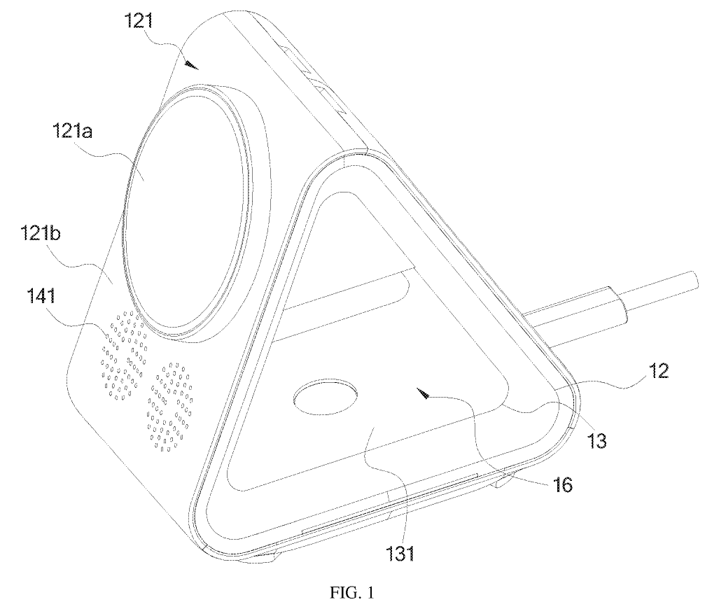

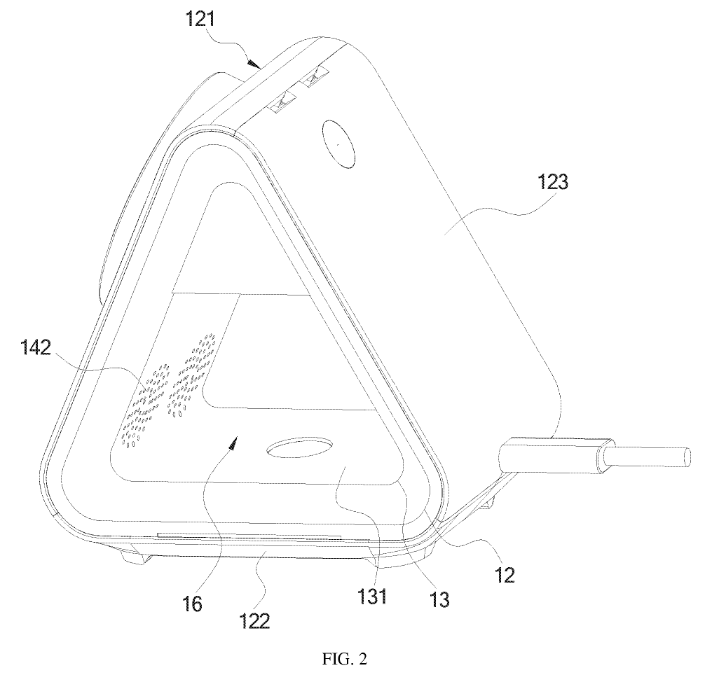

In some embodiments, as shown in FIGS. 1-3, the wireless charging device may include a main body 10, a first wireless charging assembly 21, a first fan 30, and a second fan 40.

The main body 10 may define an accommodating cavity 11. The main body 10 may include a first side plate 121 configured to carry a device 2 to be charged. The main body 10 may be configured to provide support for other components in the wireless charging device. In a case where the wireless charging device performs wireless charging on the device 2 to be charged, the device 2 to be charged may be placed on the first side plate 121, and the first side plate 121 may be configured to carry or hold the device 2 to be charged. A preparation material of the first side plate 121 may be a non-metallic material with relatively good thermal conductivity, such as graphite, silicon oxide, or the like, which may facilitate heat dissipation of the first wireless charging assembly 21 while reducing the chance of the first side plate 121 shielding electromagnetic waves generated from the first wireless charging assembly 21. Apparently, the material of the first side plate 121 may include other materials. The device 2 to be charged may be a mobile phone, a tablet computer, a game device, an augmented reality (AR) device, a data storage device, an audio playback device, a video playback device, a desktop computing device, or a wearable device such as an electronic watch, electronic glasses, an electronic helmet, an electronic bracelet, an electronic necklace, or the like.

The first wireless charging assembly 21 may be disposed in the accommodating cavity 11. It should be noted that, as the name implies, the first wireless charging assembly 21 may be configured to perform wireless charging on the device 2 to be charged, such that the wireless charging device may have a wireless charging function. The first wireless charging assembly 21 may be configured to rely on electromagnetic wave transmission and to convert electromagnetic wave energy into electrical energy, thereby ultimately realizing wireless charging. A working principle of wireless charging may have already been disclosed in the related art, and thus may not be described in detail in the embodiments of the present disclosure.

The first fan 30 may be disposed on the main body 10. The first fan 30 may define a first air outlet 32. An outer surface of the first side plate 121 may define a first exhaust port 141. The first fan 30 may be configured to blow air toward the first exhaust port 141 through the first air outlet 32. It should be noted that, in a case where the device 2 to be charged is carried on the first side plate 121 for charging and the first fan 30 is turned on, then air may be blown toward the device 2 to be charged through the first exhaust port 141, thereby improving heat dissipation efficiency of the device 2 to be charged.

The second fan 40 may be disposed on the main body 10. The second fan 40 may define a second air outlet 42. The second fan 40 may be configured to blow air toward the first wireless charging assembly 21 through the second air outlet 42. It should be noted that, in a case where the wireless charging device charges the device 2 to be charged and the second fan 40 is turned on, air blown toward the first wireless charging assembly 21 may be discharged through a second exhaust port 144, thereby improving heat dissipation efficiency of the first wireless charging assembly 21.

It should be noted that, in a case where the first wireless charging assembly 21 charges the device 2 to be charged, the first wireless charging assembly 21 and electronic components in the device 2 to be charged may generate a large amount of heat, such that temperatures inside the wireless charging device and inside the device 2 to be charged may easily reach a preset temperature protection point. In this way, the wireless charging device and the device 2 to be charged may be caused to actively reduce charging power, thereby resulting in a reduction in charging efficiency of the device 2 to be charged.

In some embodiments of the present disclosure, in a case where the wireless charging device charges the device 2 to be charged, the first fan 30 and the second fan 40 may blow air toward the device 2 to be charged and the first wireless charging assembly 21, respectively. Cold air may carry away heat generated from the device 2 to be charged and the first wireless charging assembly 21, thereby enhancing heat dissipation of the device 2 to be charged and the first wireless charging assembly 21. In this way, temperature rise rates of the device 2 to be charged and the wireless charging device may be delayed, enabling the device 2 to be charged to remain in a fast charging state for a relatively long time, thereby improving charging efficiency of the device 2 to be charged and shortening charging time.

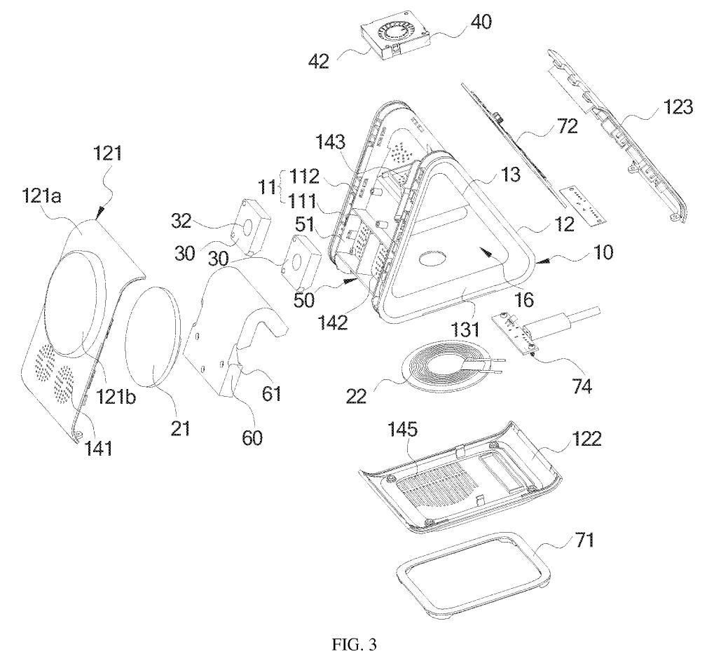

In some embodiments, as shown in FIGS. 3-5, the first fan 30 and the second fan 40 may both be disposed in the accommodating cavity 11, such that internal space of the accommodating cavity 11 may be fully utilized, and an overall volume of the wireless charging device may be reduced.

The first fan 30 may further define a first air inlet 31. The second fan 40 may define a second air inlet 41. The main body 10 may define a first air intake port 142, a second air intake port 143, and a second exhaust port 144. The first air inlet 31 may be in communication with an exterior of the accommodating cavity 11 through the first air intake port 142. The second air inlet 41 may be in communication with the exterior of the accommodating cavity 11 through the second air intake port 143. The second air outlet 42 may be in communication with the exterior of the accommodating cavity 11 through the second exhaust port 144.

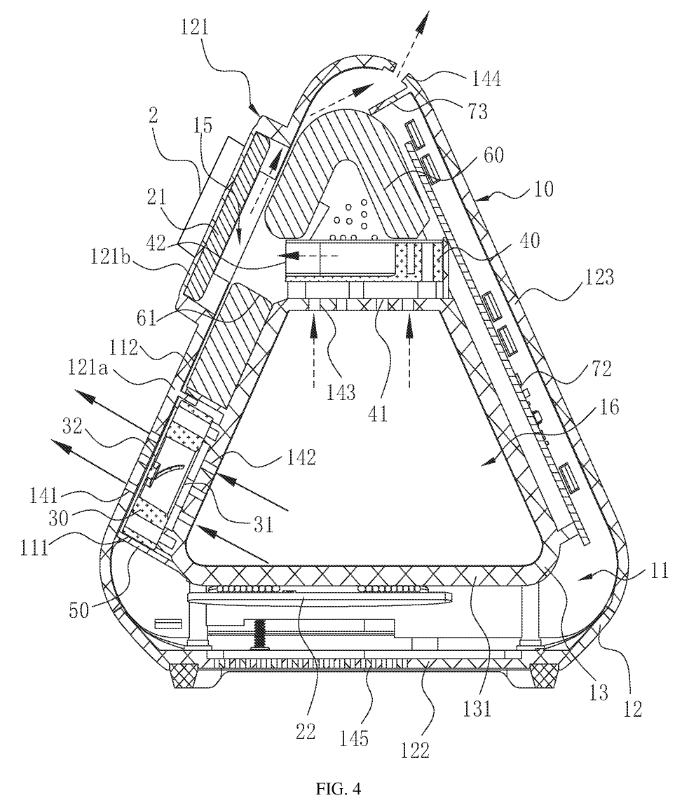

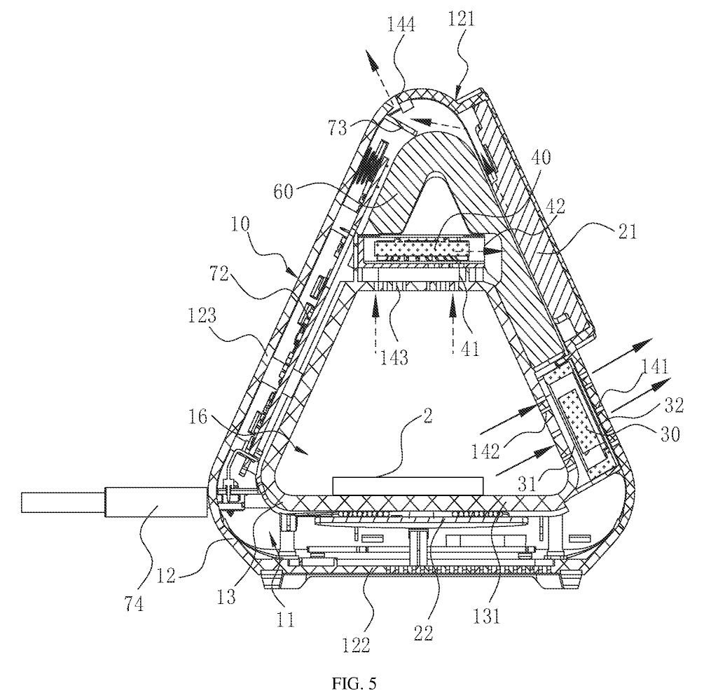

It may be understood that, as shown in FIGS. 4 and 5, directions indicated by thick solid arrows may be flow directions of airflow generated from the first fan 30, and directions indicated by dashed arrows may be flow directions of airflow generated from the second fan 40. In a case where the first fan 30 is turned on, airflow generated from the first fan 30 may sequentially pass through the first air intake port 142, the first air inlet 31, the first air outlet 32, and the first exhaust port 141. In a case where the second fan 40 is turned on, airflow generated from the second fan 40 may sequentially pass through the second air intake port 143, the second air inlet 41, the second air outlet 42, and the second exhaust port 144. Low-temperature air in an external environment of the accommodating cavity 11 may enter the accommodating cavity 11 through the first air intake port 142 and the second air intake port 143. In a case where airflow discharged from the second air outlet 42 of the second fan 40 passes through the first wireless charging assembly 21, heat generated from the first wireless charging assembly 21 may be carried away, such that a temperature of the airflow discharged from the second air outlet 42 may increase. A relatively high-temperature airflow may be discharged from the accommodating cavity 11 through the second exhaust port 144, thereby carrying heat in the accommodating cavity 11 out of the accommodating cavity 11.

As further shown in FIGS. 3-5, in some embodiments of the present disclosure, the wireless charging device may further include a partition structure 50. The partition structure 50 may be disposed in the accommodating cavity 11 and may be connected to the main body 10. The partition structure 50 may divide the accommodating cavity 11 into a first cavity 111 and a second cavity 112. The first cavity 111 and the second cavity 112 may not be in communication with each other. The first fan 30 may be disposed in the first cavity 111. The first air intake port 142 and the first exhaust port 141 may both be in communication with the first cavity 111. The first wireless charging assembly 21 and the second fan 40 may both be disposed in the second cavity 112. The second air intake port 143 and the second exhaust port 144 may both be in communication with the second cavity 112. The partition structure 50 may include a partition plate 51 disposed around the first fan 30. The partition plate 51 may divide the accommodating cavity 11 into the first cavity 111 and the second cavity 112 that are not in communication with each other. The partition plate 51 may be integrally formed with the main body 10, or may be formed separately from the main body 10 and then assembled with the main body 10 through welding, adhesive bonding, riveting, threaded connection, snap-fitting, or other connection manners.

It should be noted that, through separating an air duct of the first fan 30 from an air duct of the second fan 40 through the partition structure 50, hot air that has passed through the first wireless charging assembly 21 may be blocked from entering the air duct of the first fan 30, thereby reducing the chance of the hot air that has passed through the first wireless charging assembly 21 being blown toward the device 2 to be charged through the first exhaust port 141. As such, only cold air generated from the first fan 30 may be blown toward the device 2 to be charged through the first exhaust port 141, which may improve heat dissipation efficiency of the device 2 to be charged. In addition, airflow generated from the first fan 30 may be concentrated toward the device 2 to be charged, and airflow generated from the second fan 40 may be concentrated toward the first wireless charging assembly 21, thereby further improving heat dissipation efficiency of the device 2 to be charged and the first wireless charging assembly 21.

In some embodiments of the present disclosure, the first air inlet 31 may face toward the first air intake port 142, and the first air outlet 32 may face the first exhaust port 141, such that air entering the accommodating cavity 11 through the first air intake port 142 may rapidly enter the first air inlet 31, and such that the first air outlet 32 may directly blow air toward the device 2 to be charged. In this way, heat exchange between air entering the accommodating cavity 11 through the first air intake port 142 and air inside the accommodating cavity 11 may be reduced, such that temperatures of air sucked in and discharged from the first fan 30 may be maintained at a relatively low level, thereby improving heat dissipation efficiency of the device 2 to be charged.

Further, a side of the first fan 30 defining the first air inlet 31 may be in contact with the inner shell 13, and a side of the first fan 30 defining the first air outlet 32 may be in contact with the outer shell 12, so as to further reduce heat exchange between air entering the accommodating cavity 11 through the first air intake port 142 and air inside the accommodating cavity 11, thereby further improving a heat dissipation effect of the first fan 30 on the device 2 to be charged.

In some embodiments of the present disclosure, the second exhaust port 144 may face toward a direction away from the first side plate 121, so as to reduce the chance of hot air discharged from the second exhaust port 144 being blown toward the device 2 to be charged. The orientation of the second exhaust port 144 may be substantially perpendicular to an outer surface of the first side plate 121, or the orientation of the second exhaust port 144 may form other included angles with the outer surface of the first side plate 121. The included angle may be 30 degrees, 45 degrees, 60 degrees, 75 degrees, or other angles.

As further shown in FIGS. 3-5, in some embodiments of the present disclosure, the wireless charging device may further include a heat dissipation member 60. The heat dissipation member 60 may be disposed in the accommodating cavity 11. A portion of the first wireless charging assembly 21 may be disposed at a distance from the heat dissipation member 60, so as to form a first heat dissipation air duct 15 between the second portion 121b and the heat dissipation member 60. The second air outlet 42 may be in communication with the second exhaust port 144 through the first heat dissipation air duct 15.

It may be understood that heat generated from the first wireless charging assembly 21 may be transferred to the heat dissipation member 60 and may be dissipated through the heat dissipation member 60. The heat dissipation member 60 may increase a heat dissipation area and heat dissipation efficiency of the first wireless charging assembly 21. In some embodiments of the present disclosure, air may be blown toward the first heat dissipation air duct 15 by the second fan 40, and airflow passing through the first heat dissipation air duct 15 may carry away heat from both the first wireless charging assembly 21 and the heat dissipation member 60, thereby further improving heat dissipation efficiency of the first wireless charging assembly 21.

Further, the second fan 40 may be disposed on a side of the heat dissipation member 60 away from the first wireless charging assembly 21. The heat dissipation member 60 may define a ventilation port 61. The ventilation port 61 may be in communication with the second air outlet 42 and the first heat dissipation air duct 15. It may be understood that airflow discharged from the second air outlet 42 may sequentially pass through the ventilation port 61, the first heat dissipation air duct 15, and the second exhaust port 144 from the side of the heat dissipation member 60 close to the first wireless charging assembly 21. The ventilation port 61 may increase a contact area between airflow discharged from the second air outlet 42 and the heat dissipation member 60, thereby improving heat dissipation efficiency of the heat dissipation member 60. The ventilation port 61 may be defined on a middle region of the heat dissipation member 60, or may be disposed on an edge region of the heat dissipation member 60.

In some embodiments of the present disclosure, the first fan 30 may be an axial-flow fan, and the second fan 40 may be a centrifugal fan. It may be understood that, an axial-flow fan may have relatively low cost and may be easy to install. Airflow generated from the axial-flow fan may be relatively uniform and may have a relatively large air volume, which may rapidly carry away heat generated from the device 2 to be charged, thereby improving charging efficiency of the device 2 to be charged. A centrifugal fan may output a relatively large air volume with small space occupation. Airflow generated from the centrifugal fan may have characteristics such as high air pressure, high flow velocity, and strong penetration capability, etc., such that heat generated from the first wireless charging assembly 21 and the heat dissipation member 60 may be effectively carried away through the first heat dissipation air duct 15. It should further be noted that, a quantity of the first fan 30 may be one, two, or more. A quantity of the second fan 40 may be one, two, or more. The quantities of the first fan 30 and the second fan 40 may be selected according to actual requirements, which will not be limited in the present disclosure.

As further shown in FIGS. 3-5, in some embodiments of the present disclosure, the first side plate 121 may include a first portion 121a and a second portion 121b. The second portion 121b may be configured to carry the device 2 to be charged. The second portion 121b may be connected to the first portion 121a. The second portion 121b may protrude relative to the first portion 121a in a direction away from the accommodating cavity 11.

The first exhaust port 141 may be defined on the first portion 121a. In a case where charging is needed to be performed on the device 2 to be charged, the device 2 to be charged may be placed on the second portion 121b. In this case, since the second portion 121b may protrude relative to the first portion 121a in the direction away from the accommodating cavity 11, the second portion 121b and the first portion 121a may form a step-like structure and a gap may be formed or defined between the device 2 to be charged and the first portion 121a. In a case where the first fan 30 blows air through the first exhaust port 141, cold air may flow through the gap to carry away heat from a surface of the device 2 to be charged and an outer surface of the first side plate 121, thereby realizing heat dissipation of both the first wireless charging assembly 21 and the device 2 to be charged, and further improving heat dissipation efficiency. In addition, for a device 2 to be charged with a rear camera that protrudes relative to a main body of the device 2 to be charged, the second portion 121b may separate the main body of the device 2 to be charged from the first portion 121a and may provide sufficient spacing for the rear camera, so as to reduce contact between the rear camera and the first portion 121a that may hinder the device 2 to be charged from being stably placed on the second portion 121b.

Further, the first wireless charging assembly 21 may be disposed in a space defined or enclosed by the second portion 121b, so as to further reduce a distance between the first wireless charging assembly 21 and the device 2 to be charged, thereby improving charging efficiency. In this case, a distance between the first portion 121a and the first wireless charging assembly 21 may be reduced, which may facilitate heat dissipation of the first wireless charging assembly 21 through cold air flowing through the gap.

Further, the first exhaust port 141 may be located below the second portion 121b, such that air blown from the first exhaust port 141 may flow upward from a bottom of the first portion 121a. In this way, contact areas between airflow and the device 2 to be charged and between airflow and the outer surface of the first side plate 121 may be increased, further improving heat dissipation efficiency.

In some embodiments, a magnet may be directly disposed on the second portion 121b or disposed in a region of the first portion 121a adjacent to the second portion 121b. In a case where the device 2 to be charged is placed on the second portion 121b, attraction between the magnet and metal or a magnetic object in the device 2 to be charged may be utilized, thereby reducing the chance of the device 2 to be charged falling off the second portion 121b.

As shown in FIGS. 1-5, in some embodiments of the present disclosure, the main body 10 may include an outer shell 12 and an inner shell 13. The outer shell 12 may include the first side plate 121. The inner shell 13 may be disposed inside the outer shell 12 and may be connected to the outer shell 12. The accommodating cavity 11 may be formed or defined between the inner shell 13 and the outer shell 12. The inner shell 13 may define a heat dissipation space 16 on a side away from the outer shell 12.

The first exhaust port 141 and the second exhaust port 144 may both be defined on the outer shell 12. The first air intake port 142 and the second air intake port 143 may both be defined on the inner shell 13 and may be in communication with the heat dissipation space 16. It may be understood that the heat dissipation space 16 may be in communication with an external atmosphere outside the accommodating cavity 11. The inner shell 13 may increase a heat dissipation area of the main body 10, such that heat inside the accommodating cavity 11 may be dissipated not only through an outer surface of the first side plate 121 but also through an inner surface of the inner shell 13, thereby improving heat dissipation efficiency of the wireless charging device. In addition, compared with defining the first air intake port 142 and the second air intake port 143 at a bottom of the main body 10, in some embodiments of the present disclosure, the first air intake port 142 and the second air intake port 143 may be defined on the inner shell 13 to allow both the first air intake port 142 and the second air intake port 143 to draw air with a lower temperature through the heat dissipation space 16. In this way, not only airflow resistance of the first air intake port 142 and the second air intake port 143 may be reduced, but also a larger air intake space may be provided, thereby further improving heat dissipation efficiency.

Further, as shown in FIGS. 1-5, an overall shape of the main body 10 may substantially be a triangular ring shape, such that an overall structure of the main body 10 may be stable.

As shown in FIGS. 1-5, in some embodiments of the present disclosure, the outer shell 12 may further include a first bottom plate 122. The inner shell 13 may include a second bottom plate 131 disposed opposite to the first bottom plate 122. The wireless charging device may further include a second wireless charging assembly 22. The second wireless charging assembly 22 may be disposed in the accommodating cavity 11 and may be located between the first bottom plate 122 and the second bottom plate 131. It should be noted that the second wireless charging assembly 22 and the first wireless charging assembly 21 may be independent of each other. The second wireless charging assembly 22 and the first wireless charging assembly 21 may operate independently. The second wireless charging assembly 22 and the first wireless charging assembly 21 may operate simultaneously. In this way, the wireless charging device may simultaneously provide wireless charging for a plurality of devices to be charged. For example, a mobile phone may be placed on the first side plate 121. The first wireless charging assembly 21 may be configured to provide wireless charging for a relatively large device 2 to be charged, such as the mobile phone. Further, a relatively small device 2 to be charged, such as an electronic watch, may be placed on the second bottom plate 131. The second wireless charging assembly 22 may be configured to provide wireless charging for the electronic watch.

In some embodiments, the first bottom plate 122 may further define a heat dissipation hole 145. The accommodating cavity 11 may be in communication with an exterior of the accommodating cavity 11 through the heat dissipation hole 145, such that the second wireless charging assembly 22 may dissipate heat through the heat dissipation hole 145.

In some embodiments of the present disclosure, the wireless charging device may further include a foot pad 71. The foot pad 71 may be disposed on a bottom of the first bottom plate 122 and may be connected to the first bottom plate 122. In a case where the wireless charging device is placed on a support surface such as a countertop or a desktop, the foot pad 71 may increase friction with the support surface, such that the wireless charging device may be placed stably. In addition, the foot pad 71 may suspend the first bottom plate 122, thereby facilitating heat dissipation of the second wireless charging assembly 22. A preparation material of the foot pad 71 may be silicone, plastic, or other materials.

In some embodiments, the first wireless charging assembly 21 may include a first charging coil. The second wireless charging assembly 22 may include a second charging coil. It may be understood that a charging coil, after being energized, may be configured to generate a magnetic field and to provide wireless charging for a device 2 to be charged. A device 2 to be charged that supports wireless charging may further include a receiving coil. In a case where the receiving coil is disposed corresponding to the charging coil, electromagnetic wave energy generated from the charging coil may be converted into electrical energy by the receiving coil, thereby realizing wireless charging of the device 2 to be charged.

As further shown in FIGS. 3-5, the wireless charging device may further include a control circuit board 72. The control circuit board 72 may be configured to control operation of the first charging coil and the second charging coil, so as to control parameters, such as input current magnitudes of the first charging coil and the second charging coil. The control circuit board 72 may include two control circuits that are configured to respectively control the first charging coil and the second charging coil. The two control circuits may be independent of each other, such that the first charging coil and the second charging coil may operate independently.

In some embodiments of the present disclosure, the outer shell 12 may further include a second side plate 123. The second side plate 123 may be disposed on a side of the first wireless charging assembly 21 away from the first side plate 121. The first wireless charging assembly 21 may be disposed close to the first side plate 121. The control circuit board 72 may be disposed close to the second side plate 123. It may be understood that, in a case where the device 2 to be charged is placed on the first side plate 121, since the first wireless charging assembly 21 may be disposed close to the first side plate 121, a distance between the first wireless charging assembly 21 and the device 2 to be charged may be relatively small, thereby improving wireless charging efficiency of the device 2 to be charged. In addition, disposing the control circuit board 72 close to the second side plate 123 may increase a distance between the control circuit board 72 and the first wireless charging assembly 21. In this way, heat generated from the control circuit board 72 may further be directly dissipated through the second side plate 123, thereby improving heat dissipation efficiency of the control circuit board 72.

In some embodiments of the present disclosure, an air guide baffle 73 may further be disposed in the accommodating cavity 11. The air guide baffle 73 may be connected to the main body 10. The air guide baffle 73 may be disposed at the second exhaust port 144 or may be disposed adjacent to the second exhaust port 144. The air guide baffle 73 may be located between the second exhaust port 144 and the control circuit board 72 and may separate the second wireless charging assembly 22 from the control circuit board 72, thereby blocking hot air that has passed through the second wireless charging assembly 22 from being blown toward the control circuit board 72.

In some embodiments of the present disclosure, the wireless charging device may further include a power connection assembly 74. The power connection assembly 74 may be configured to connect the first wireless charging assembly 21 and the second wireless charging assembly 22 to a power source, such as a power grid. In this way, the power source may be configured to supply power to the first wireless charging assembly 21 and the second wireless charging assembly 22. The power connection assembly 74 may include components such as a power connection port and a charging circuit board.

In some embodiments of the present disclosure, during assembly of the wireless charging device, the first fan 30 and the second fan 40 may be first fixed in the accommodating cavity 11 of the main body 10 through screws or the like. A conductive wire of the first fan 30 and a conductive wire of the second fan 40 may be fixed through a wire groove designed inside the main body 10. Then, the heat dissipation member 60 may be fixed in the accommodating cavity 11 of the main body 10. The first wireless charging assembly 21 may be assembled or disposed into a space defined by the second portion 121b. The conductive wire of the first fan 30 and the conductive wire of the second fan 40 may be soldered to the control circuit board 72. A conductive wire of the first wireless charging assembly 21 may be soldered to the control circuit board 72. Next, the control circuit board 72 may be fixed in the accommodating cavity 11. The second wireless charging assembly 22 and the power connection assembly 74 may be assembled or disposed at a bottom of the accommodating cavity 11. A conductive wire of the second wireless charging assembly 22 may be soldered to the control circuit board 72. After that, the first bottom plate 122 may be fixed, and finally the foot pad 71 may be attached to a bottom of the first bottom plate 122.

In the drawings of the present embodiment, identical or similar reference numerals may correspond to identical or similar components. In the description of the present disclosure, it should be understood that terms indicating orientations or positional relationships such as “upper”, “lower”, “left”, and “right” may be based on orientations or positional relationships shown in the drawings, and may be only for convenience of describing the present disclosure and simplifying the description, rather than indicating or implying that the indicated devices or elements must have specific orientations, or must be constructed and operated in specific orientations. Thus, terms describing positional relationships in the drawings may be used only for illustrative purposes and may not be construed as limiting the present patent. Those skilled in the art may understand specific meanings of the above terms according to specific circumstances.

The above descriptions may be only preferred embodiments of the present disclosure and may not be intended to limit the present disclosure. Any modifications, equivalent substitutions, or improvements made within the spirit and principles of the present disclosure may be included within the scope of protection of the present disclosure.

1. A wireless charging device, comprising:
a main body, defining an accommodating cavity and comprising a first side plate, wherein the first side plate is configured to carry a device to be charged and an outer surface of the first side plate defines a first exhaust port;
a first wireless charging assembly, disposed in the accommodating cavity;
a first fan, disposed on the main body, wherein the first fan defines a first air outlet and the first fan is configured to blow air toward the first exhaust port through the first air outlet; and
a second fan, disposed on the main body, wherein the second fan defines a second air outlet and the second fan is configured to blow air toward the first wireless charging assembly through the second air outlet.

2. The wireless charging device as claimed in claim 1, wherein the first fan and the second fan are both disposed in the accommodating cavity;
wherein the first fan further defines a first air inlet, the second fan defines a second air inlet, the main body defines a first air intake port, a second air intake port, and a second exhaust port, the first air inlet is in communication with an exterior of the accommodating cavity through the first air intake port, the second air inlet is in communication with the exterior of the accommodating cavity through the second air intake port, and the second air outlet is in communication with the exterior of the accommodating cavity through the second exhaust port.

3. The wireless charging device as claimed in claim 2, further comprising:
a partition structure, disposed in the accommodating cavity and connected to the main body, wherein the partition structure divides the accommodating cavity into a first cavity and a second cavity that are not in communication with each other;
wherein the first fan is disposed in the first cavity, the first air intake port and the first exhaust port are both in communication with the first cavity, the first wireless charging assembly and the second fan are both disposed in the second cavity, and the second air intake port and the second exhaust port are both in communication with the second cavity.

4. The wireless charging device as claimed in claim 2, wherein the first air inlet faces toward the first air intake port and the first air outlet faces toward the first exhaust port.

5. The wireless charging device as claimed in claim 2, wherein the second exhaust port faces toward a direction away from the first side plate.

6. The wireless charging device as claimed in claim 2, further comprising:
a heat dissipation member, disposed in the accommodating cavity, wherein a portion of the first wireless charging assembly is disposed at a distance from the heat dissipation member to form a first heat dissipation air duct between the second portion and the heat dissipation member, and the second air outlet is in communication with the second exhaust port through the first heat dissipation air duct.

7. The wireless charging device as claimed in claim 6, wherein the second fan is disposed on a side of the heat dissipation member away from the first wireless charging assembly, the heat dissipation member defines a ventilation port, and the ventilation port is in communication with the second air outlet and the first heat dissipation air duct.

8. The wireless charging device as claimed in claim 2, wherein the main body comprises:
an outer shell, comprising the first side plate; and
an inner shell, disposed inside the outer shell and connected to the outer shell, wherein the accommodating cavity is defined between the inner shell and the outer shell, and the inner shell defines a heat dissipation space on a side away from the outer shell;
wherein the first exhaust port and the second exhaust port are both defined on the outer shell, and the first air intake port and the second air intake port are both defined on the inner shell and are in communication with the heat dissipation space.

9. The wireless charging device as claimed in claim 1, wherein the main body comprises:
an outer shell, comprising the first side plate and a first bottom plate; and
an inner shell, disposed inside the outer shell and connected to the outer shell, wherein the accommodating cavity is defined between the inner shell and the outer shell, the inner shell defines a heat dissipation space on a side away from the outer shell, and the inner shell comprises a second bottom plate disposed opposite to the first bottom plate;
wherein the wireless charging device further comprises a second wireless charging assembly, and the second wireless charging assembly is disposed in the accommodating cavity and located between the first bottom plate and the second bottom plate.

10. The wireless charging device as claimed in claim 1, wherein the first side plate comprises:
a first portion; and
a second portion, configured to carry the device to be charged, wherein the second portion is connected to the first portion and protrudes relative to the first portion in a direction away from the accommodating cavity, and the first wireless charging assembly is disposed in a space defined by the second portion;
wherein the first exhaust port is defined on the first portion.

11. A wireless charging device, comprising:
a main body, defining an accommodating cavity and comprising a first side plate, wherein the first side plate is configured to carry a device to be charged and an outer surface of the first side plate defines a first exhaust port;
a first wireless charging assembly, disposed in the accommodating cavity;
a first fan, disposed on the main body, wherein the first fan defines a first air outlet, the first fan is configured to blow air toward the first exhaust port through the first air outlet, the first air outlet faces toward the first exhaust port, and a side of the first fan that defines the first air outlet is in contact with the main body; and
a second fan, disposed on the main body, wherein the second fan defines a second air outlet and the second fan is configured to blow air toward the first wireless charging assembly through the second air outlet.

12. The wireless charging device as claimed in claim 11, wherein the first fan and the second fan are both disposed in the accommodating cavity;
wherein the first fan further defines a first air inlet, the second fan defines a second air inlet, the main body defines a first air intake port, a second air intake port, and a second exhaust port, the first air inlet is in communication with an exterior of the accommodating cavity through the first air intake port, the second air inlet is in communication with the exterior of the accommodating cavity through the second air intake port, and the second air outlet is in communication with the exterior of the accommodating cavity through the second exhaust port.

13. The wireless charging device as claimed in claim 12, further comprising:
a partition structure, disposed in the accommodating cavity and connected to the main body, wherein the partition structure divides the accommodating cavity into a first cavity and a second cavity that are not in communication with each other;
wherein the first fan is disposed in the first cavity, the first air intake port and the first exhaust port are both in communication with the first cavity, the first wireless charging assembly and the second fan are both disposed in the second cavity, and the second air intake port and the second exhaust port are both in communication with the second cavity.

14. The wireless charging device as claimed in claim 12, wherein the first air inlet faces toward the first air intake port.

15. The wireless charging device as claimed in claim 12, wherein the second exhaust port faces toward a direction away from the first side plate.

16. The wireless charging device as claimed in claim 12, further comprising:
a heat dissipation member, disposed in the accommodating cavity, wherein a portion of the first wireless charging assembly is disposed at a distance from the heat dissipation member to form a first heat dissipation air duct between the second portion and the heat dissipation member, and the second air outlet is in communication with the second exhaust port through the first heat dissipation air duct.

17. The wireless charging device as claimed in claim 16, wherein the second fan is disposed on a side of the heat dissipation member away from the first wireless charging assembly, the heat dissipation member defines a ventilation port, and the ventilation port is in communication with the second air outlet and the first heat dissipation air duct.

18. The wireless charging device as claimed in claim 12, wherein the main body comprises:
an outer shell, comprising the first side plate; and
an inner shell, disposed inside the outer shell and connected to the outer shell, wherein the accommodating cavity is defined between the inner shell and the outer shell, and the inner shell defines a heat dissipation space on a side away from the outer shell;
wherein the first exhaust port and the second exhaust port are both defined on the outer shell, and the first air intake port and the second air intake port are both defined on the inner shell and are in communication with the heat dissipation space.

19. The wireless charging device as claimed in claim 11, wherein the main body comprises:
an outer shell, comprising the first side plate and a first bottom plate; and
an inner shell, disposed inside the outer shell and connected to the outer shell, wherein the accommodating cavity is defined between the inner shell and the outer shell, the inner shell defines a heat dissipation space on a side away from the outer shell, and the inner shell comprises a second bottom plate disposed opposite to the first bottom plate;
wherein the wireless charging device further comprises a second wireless charging assembly, and the second wireless charging assembly is disposed in the accommodating cavity and located between the first bottom plate and the second bottom plate.

20. The wireless charging device as claimed in claim 11, wherein the first side plate comprises:
a first portion; and
a second portion, configured to carry the device to be charged, wherein the second portion is connected to the first portion and protrudes relative to the first portion in a direction away from the accommodating cavity, and the first wireless charging assembly is disposed in a space defined by the second portion;
wherein the first exhaust port is defined on the first portion.
